(19) United States
(12) Patent Application Publication
(10) Pub. No.: US 2025/0255127 A1
(43) Pub. Date: Aug. 7, 2025

(54) LIGHT EMITTING DEVICE, IMAGE FORMING DEVICE, IMAGE CAPTURING DEVICE, DISPLAY DEVICE, ELECTRONIC APPARATUS, AND WEARABLE DEVICE

(71) Applicant: CANON KABUSHIKI KAISHA, Tokyo (JP)

(72) Inventors: MASAAKI IWANE, Kanagawa (JP); TAKANORI YAMASHITA, Tokyo (JP); SHOJI KONO, Tokyo (JP); SHUSUKE YANAGAWA, Kanagawa (JP)

(21) Appl. No.: 19/041,103

(22) Filed: Jan. 30, 2025

(30) Foreign Application Priority Data
Feb. 7, 2024 (JP) 2024-017431
Dec. 13, 2024 (JP) 2024-219010

(51) Int. Cl. H10K 59/131; G03G 15/04; G06F 1/16; H04N 23/53; H10K 59/121; H10K 59/127

(52) U.S. Cl. CPC H10K 59/131; H10K 59/1216; H10K 59/127; G03G 15/04054; G06F 1/1601; H04N 23/53

(57) ABSTRACT

A light emitting device comprises a substrate that includes a light emitting pixel array including a plurality of light emitting pixels each including a light emitting element and a driving transistor configured to drive the light emitting element, a power supply wiring configured to supply a power supply voltage to the driving transistor, and a capacitance portion including a first electrode and a second electrode. The light emitting element includes a first electrode layer, a light emitting layer arranged on the first electrode layer, and a second electrode layer arranged on the light emitting layer. The first electrode and the second electrode are located at positions lower than a bottom surface of the first electrode layer, the first electrode is electrically connected to the power supply wiring, and the second electrode is electrically connected to the second electrode layer.

### BACKGROUND OF THE INVENTION

### Field of the Invention

The present invention relates to a light emitting device, an image forming device, an image capturing device, a display device,, an electronic apparatus, and a wearable device.

### Description of the Related Art

There is a display device including a light emitting device that uses an organic light-emitting element (organic EL element). Japanese Patent Laid-Open No. 2013-238723 (to be referred to as PTL 1 hereinafter) describes an electrooptical device in which a power supply wiring surrounds a light emitting element and an intermediate electrode connecting the anode of the light emitting element and a transistor configured to control a current flowing to the light emitting element. PTL 1 describes that this can reduce image quality deterioration caused by noise affecting the portion from the region where the transistor is formed to the anode. In a light emitting device, fluctuations of a power supply voltage can generate horizontal stripes in the display.

### SUMMARY OF THE INVENTION

According to the present disclosure, it is possible to provide a technique capable of suppressing the influence of fluctuations of a power supply voltage on the display of a light emitting device.

According to one aspect of the disclosure, there is provided a light emitting device comprises a substrate that includes a light emitting pixel array including a plurality of light emitting pixels each including a light emitting element and a driving transistor configured to drive the light emitting element, a power supply wiring configured to supply a power supply voltage to the driving transistor, and a capacitance portion including a first electrode and a second electrode. The light emitting element includes a first electrode layer, a light emitting layer arranged on the first electrode layer, and a second electrode layer arranged on the light emitting layer. The first electrode and the second electrode are located at positions lower than a bottom surface of the first electrode layer, the first electrode is electrically connected to the power supply wiring, and the second electrode is electrically connected to the second electrode layer.

Further features of the present invention will become apparent from the following description of exemplary embodiments with reference to the attached drawings.

### BRIEF DESCRIPTION OF THE DRAWINGS

FIG. 1 is a block diagram of a light emitting device;

FIG. 2 is a circuit diagram of a pixel;

FIG. 3 is a timing chart according to the first embodiment;

FIGS. 4A to 4C are views for explaining generation of image horizontal stripes;

FIG. 5 is a plan view of the light emitting device according to the first embodiment;

FIG. 6 is a sectional view of the light emitting device according to the first embodiment;

FIG. 7 is a sectional view of a light emitting device according to the second embodiment;

FIG. 8 is a sectional view of a light emitting device according to the third embodiment;

FIGS. 9A and 9B are views for explaining a light emitting device according to the fourth embodiment;

FIG. 10 is a view for explaining a light emitting device according to the fifth embodiment;

FIGS. 11A to 11C are schematic views showing an example of an image forming device according to an embodiment of the present invention;

FIG. 12 is a schematic view showing an example of a display device according to an embodiment of the present invention;

FIG. 13A is a schematic view showing an example of an image capturing device according to an embodiment of the present invention;

FIG. 13B is a schematic view showing an example of an electronic apparatus according to an embodiment of the present invention;

FIG. 14A is a schematic view showing an example of a display device according to an embodiment of the present invention;

FIG. 14B is a schematic view showing an example of a foldable display device;

FIG. 15A is a schematic view showing an example of a wearable device according to an embodiment of the present invention; and

FIG. 15B is a schematic view showing an example of a wearable device according to an embodiment of the present invention and showing a form including an image capturing device.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

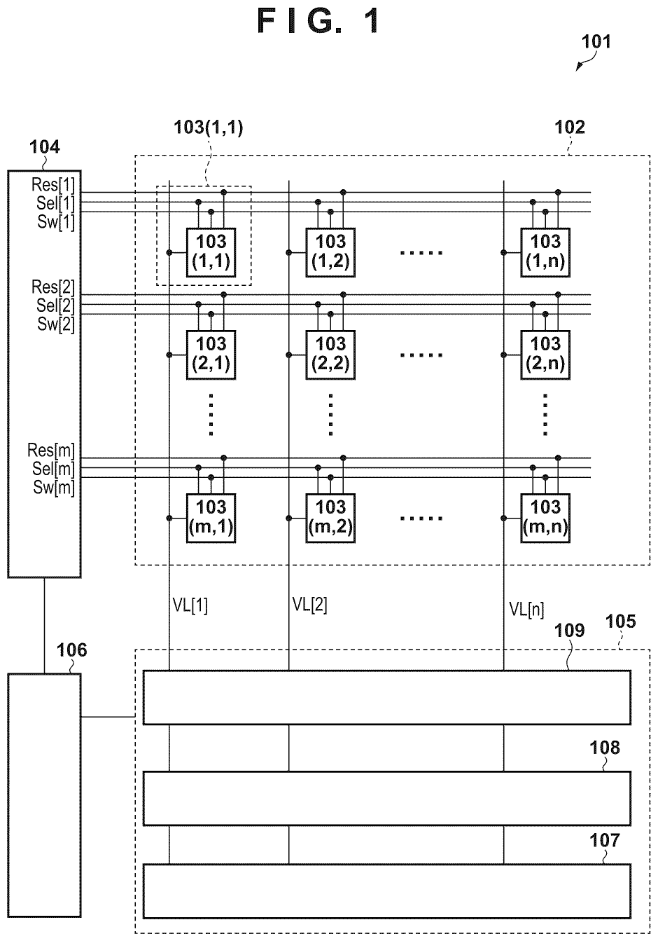

A light emitting device using an organic light emitting element (organic EL) will be taken as an example and described below. FIG. 1 is a block diagram of a light emitting device 101. The light emitting device 101 shown in FIG. 1 includes a light emitting pixel array 102 where pixels that emit light are arranged, and a peripheral circuit of the light emitting pixel array 102. The light emitting pixel array 102 of this embodiment includes a plurality of pixels 103(1, 1) to 103(m, n) two-dimensionally arranged in a matrix of m rows and n columns. Each of the pixels 103(1, 1) to 103(m, n) includes an organic light emitting element.

The peripheral circuit is a circuit for controlling the respective pixels 103(1, 1) to 103(m, n), and includes a vertical scanning circuit 104, a signal output circuit 105, and a control circuit 106. The signal output circuit 105 includes a horizontal scanning circuit 107, a column DAC circuit 108 including a plurality of digital-analog conversion (DAC) circuits, and a column driver circuit 109. The column DAC circuit 108 includes DAC circuits for n columns corresponding to the number of columns of the light emitting pixel array 102. The column driver circuit 109 includes driver circuits for n columns corresponding to the number of columns of the light emitting pixel array 102.

The horizontal scanning circuit 107 scans each DAC circuit of the column DAC circuit 108 to input a digital signal input from the control circuit 106 to each DAC circuit of the column DAC circuit 108. The DAC circuit converts the input digital signal into a corresponding analog signal. Each driver circuit of the column driver circuit 109 outputs the analog signal input from the corresponding DAC circuit to corresponding one of signal lines VL[1 to n].

The vertical scanning circuit 104 is connected to the light emitting pixel array 102 by reset signal lines Res[1 to m], write control signal lines Sel[1 to m], and light emission control signal lines Sw[1 to m].

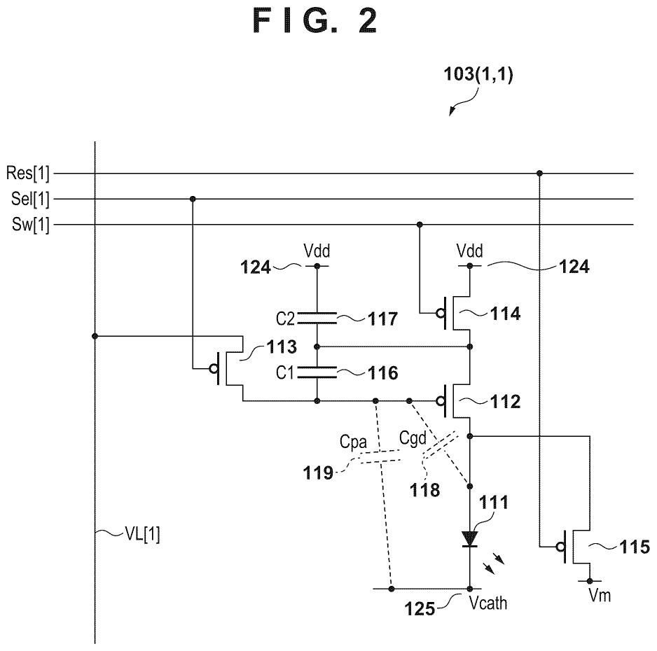

FIG. 2 is a circuit diagram of the pixel 103(1, 1) as an example of the pixel 103 shown in FIG. 1. The pixel 103(1, 1) includes an organic light emitting element 111, a driving transistor 112, a write transistor 113, a light emission control transistor 114, a reset transistor 115, a first capacitive element 116, and a second capacitive element 117. Each of the first capacitive element 116 and the second capacitive element 117 is typically a capacitance portion with an electric capacitance having a Metal-Insulator-Metal (MIM) structure. The driving transistor 112, the write transistor 113, the light emission control transistor 114, and the reset transistor 115 are p-channel MOS transistors. Note that these transistors do not all have to be p-channel transistors, and the conductivity type and the polarity may be combined and used, as appropriate.

The organic light emitting element 111 includes an organic layer including a light emitting layer between an anode electrode and a cathode electrode. The organic layer may include one or some of a hole injection layer, a hole transport layer, an electron injection layer, and an electron transport layer, as appropriate, in addition to the light emitting layer. A cathode electrode 125 shared by all pixels is provided as the cathode of the organic light emitting element 111. A cathode voltage Vcath applied to the cathode electrode 125 is typically −5 V. A parasitic capacitance 118 and a parasitic capacitance 119 are shown. Here, the parasitic capacitance 118 is a parasitic capacitance having a capacitance value Cgd between the gate electrode and the drain electrode of the driving transistor 112. The parasitic capacitance 119 is a parasitic capacitance having a capacitance value Cpa between the gate electrode of the driving transistor 112 and the cathode electrode 125.

The source electrode of the light emission control transistor 114 and one electrode of the second capacitive element 117 are connected to a power supply wiring 124. One electrode of the first capacitive element 116 and the other electrode of the second capacitive element 117 are connected, and the connection point is connected with the drain electrode of the light emission control transistor 114 and the source electrode of the driving transistor 112. The drain electrode of the driving transistor 112 is connected to the anode electrode of the organic light emitting element 111. The cathode electrode of the organic light emitting element 111 is supplied with the cathode voltage Vcath. A power supply voltage Vdd is applied to the power supply wiring 124 connected to the second capacitive element 117. The power supply voltage Vdd is typically 5 V. A voltage Vm applied to the drain electrode of the reset transistor 115 is typically −5 V.

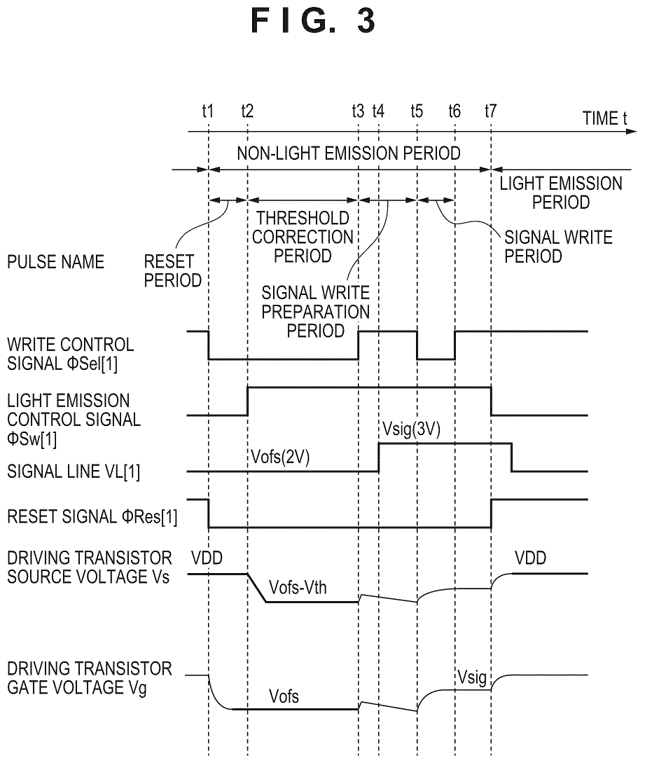

Driving of the organic light emitting element 111 according to this embodiment will be described with reference to the timing chart of FIG. 3. In FIG. 3, the abscissa represents time t. First, at time t1, a write control signal φSel[1] transitions from high level to low level, thereby setting a gate voltage Vg of the driving transistor 112 to a correction voltage (to be referred to as a Vofs hereinafter). The Vofs is typically 2 V. In addition, at time t1, a reset signal φRes[1] transitions from high level to low level. At time t2, a light emission control signal φSw[1] transitions from low level to high level, thereby setting the light emission control transistor 114 in the OFF state. The period from time t1 to time t2 is referred to as a reset period. In the reset period, the gate voltage (to be referred to as the Vg hereinafter) of the driving transistor 112 is initialized to the correction voltage Vofs, and the source voltage (to be referred to as the Vs hereinafter) thereof is initialized to the power supply voltage Vdd.

At time t3, the write control signal φSel[1] transitions from low level to high level, thereby setting the write transistor 113 in the OFF state. The period from time t2 to time t3 is referred to as a threshold correction period. In the threshold correction period, since the light emission control transistor 114 is turned off, the Vs of the driving transistor 112 changes up to Vofs−Vth as the difference voltage between the voltage Vofs and the threshold voltage (to be referred to as the Vth hereinafter) of the driving transistor 112, and settles. That is, a gate-source voltage Vgs (=Vg−Vs) of the driving transistor 112 changes to the Vth. The threshold voltage Vth is approximately the gate-source voltage Vgs at the time when a current starts to flow through the driving transistor 112. At this time, the gate voltage Vg of the driving transistor 112 is the Vofs. Accordingly, the threshold voltage Vth of the driving transistor 112 is held by the first capacitive element 116.

At time t4, the signal voltage of the signal line VL[1] switches from the voltage Vofs to a signal voltage (to be referred to as a Vsig hereinafter). The Vsig is typically 3 V. At time t5, the write control signal φSel[1] transitions from high level to low level. The period from time t3 to time t5 is referred to as a signal write preparation period.

At time t5, since the write transistor 113 is set in the ON state, the gate voltage Vg of the driving transistor 112 changes to the signal voltage Vsig of the signal line VL[1]. Letting C1 be the capacitance of the first capacitive element 116 and C2 be the capacitance of the second capacitive element 117, the source voltage Vs of the driving transistor 112 is expressed by:

Vs=Vofs−Vth+C1*(Vsig−Vofs)/(C1+C2)

At time t6, the write control signal φSel[1] transitions from low level to high level. The period from time t5 to time t6 is referred to as a signal write period.

At time t7, the light emission control signal φSw[1] transitions from high level to low level, thereby setting the light emission control transistor 114 in the ON state. At this time, the source voltage Vs of the driving transistor 112 changes to a voltage approximately equal to the power supply voltage Vdd. In addition, the reset signal φRes[1] transitions from low level to high level, thereby turning off the reset transistor 115. Thus, a current is supplied to the organic light emitting element 111 from the power supply voltage Vdd via the light emission control transistor 114 and the driving transistor 112. With this, the organic light emitting element 111 emits light. The period from time t7 is referred to as a light emission period. On the other hand, the period from time t1 to time t7 is referred to as a non-light emission period. The non-light emission period is changed row-sequentially. That is, the non-light emission period for the pixels 103(2,1) to 103(2,n) in the second row starts from time t7.

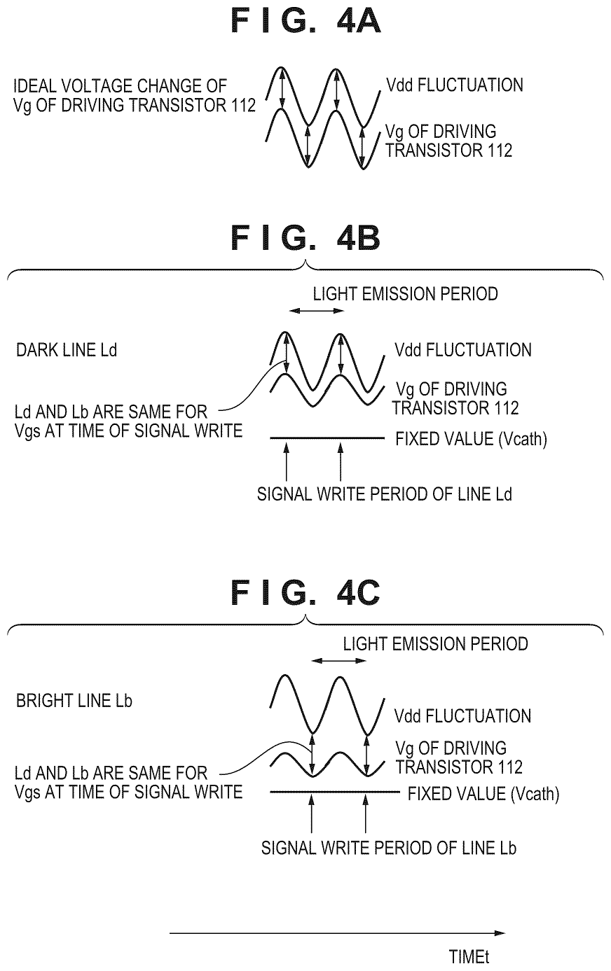

Next, the horizontal stripes generated in the display due to fluctuations of the power supply voltage Vdd will be described with reference to FIGS. 4A to 4C. In FIGS. 4A to 4C, the abscissa represents time t. First, an example (a) of the ideal voltage change of the Vg of the driving transistor 112 will be described. The power supply voltage Vdd can fluctuate due to noise from the outside of the light emitting device 101 and noise from the peripheral circuit (the vertical scanning circuit 104, the signal output circuit 105, and the control circuit 106). At this time, it is ideal that the Vg of the driving transistor 112 fluctuates at the same time and same amplitude as the power supply voltage Vdd. Since the source voltage Vs of the driving transistor 112 is the power supply voltage Vdd in the light emission period, the Vgs of the driving transistor 112 is kept constant even if the power supply voltage Vdd fluctuates. If the Vgs is constant, a source-drain current Ids of the driving transistor is constant. For the display at 60 frame per second (fps), the light emission period is 16 ms, and the non-light emission period is about 0.02 ms. Since these periods differ by three orders of magnitude, most of the display time is the light emission period. If the capacitances of the first capacitive element 116 and the second capacitive element 117 shown in FIG. 2 are sufficiently large, even if the power supply voltage Vdd fluctuates, the Vgs of the driving transistor 112 is kept constant in the light emission period.

However, the Vg of the driving transistor 112 may not fluctuate at the same time and same amplitude as the power supply voltage Vdd. This will be described using an example (b) of a dark line Ld and an example (c) of a bright line Lb shown in FIGS. 4B and 4C. In the dark line Ld, a signal is written at the positive peak of the fluctuation of the power supply voltage Vdd. Due to the cathode voltage Vcath as a fixed value and the parasitic capacitances 118 and 119 shown in FIG. 2, the Vg of the driving transistor 112 fluctuates at a smaller amplitude than the power supply voltage Vdd. Accordingly, in the dark line Ld, the Vgs of the driving transistor 112 at the negative peak of the fluctuation of the power supply voltage Vdd is smaller than the Vgs in the signal write period. The luminance is proportional to the time integral of the source-drain current Ids of the driving transistor, which is decided by the Vgs. Therefore, in the line Ld, the time integral value of the Ids supplied to the light emitting element 111 is smaller than the ideal one shown in the example (a). Hence, the line Ld can be a dark line.

On the other hand, in the bright line Lb, a signal is written at the negative peak of the fluctuation of the power supply voltage Vdd. Again, due to the cathode voltage Vcath as a fixed value and the parasitic capacitances 118 and 119 shown in FIG. 2, the Vg of the driving transistor 112 fluctuates at a smaller amplitude than the power supply voltage Vdd. Accordingly, in the bright line Lb, the Vgs of the driving transistor 112 at the positive peak of the fluctuation of the power supply voltage Vdd is larger than the Vgs in the signal write period. The luminance is proportional to the time integral of the source-drain current Ids of the driving transistor, which is decided by the Vgs. Therefore, in the line Lb, the time integral value of the Ids supplied to the light emitting element 111 is larger than the ideal one shown in the example (a). Hence, the line Lb becomes a brighter line than ideal. In this manner, the bright line Ld and the dark line Lb appear in a screen, so that horizontal stripes can be generated in the display.

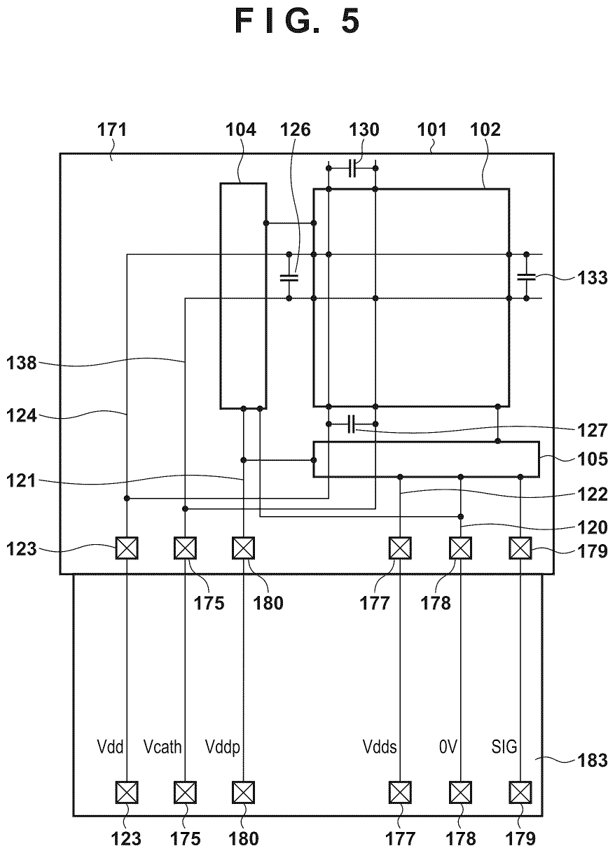

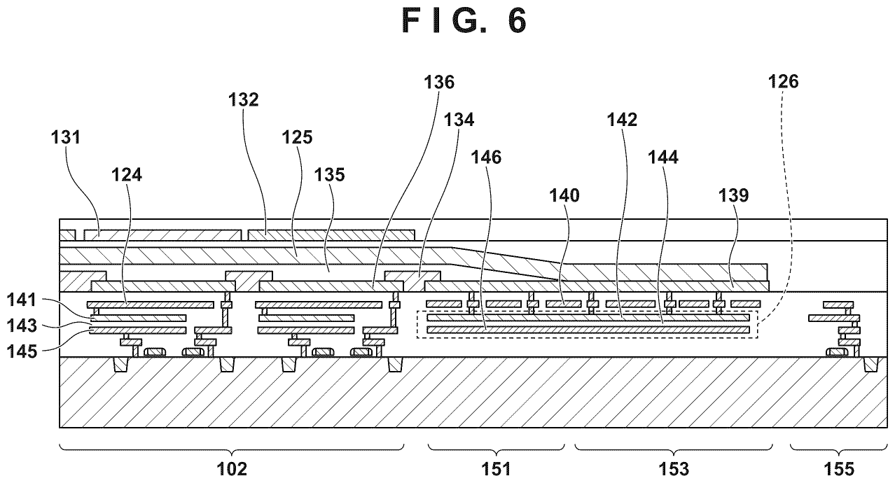

The presence of the parasitic capacitances 118 and 119 is unavoidable. In order to suppress horizontal stripes in the display even with the parasitic capacitances 118 and 119, the cathode voltage Vcath should change at the same time and same amplitude as the power supply voltage Vdd. To achieve this, the capacitive coupling between the cathode electrode 125 and the power supply wiring 124, to which the power supply voltage Vdd is applied, needs to be strengthened in the light emitting pixel array 102. A method for strengthening the capacitive coupling will be described with reference to FIGS. 5 and 6.

FIG. 5 is a plan view for explaining the light emitting device according to this embodiment. In FIG. 5, the light emitting device is provided in a substrate 171. The substrate 171 is, for example, a semiconductor substrate. A flexible cable 183 for power supply and signal input/output is connected to the substrate 171. FIG. 5 shows main wiring pads provided in the substrate 171. The wiring pads include a power supply wiring pad 123 for supplying the power supply voltage Vdd, a cathode wiring pad 175 for supplying the cathode voltage to the cathode of the organic light emitting element, and peripheral circuit power supply wiring pads 177 and 180 for supplying power supply voltages Vddp and Vdds, respectively, to the peripheral circuit. The wiring pads also include a reference power supply pad 178 for supplying a reference voltage, and a signal wiring pad 179 for input/output of various kinds of signals. FIG. 5 shows only one wiring pad for each wiring pad. However, for example, multiple signal wiring pads 179 may be provided in accordance with the number of input/output signals. Each wiring pad provided in the substrate is connected to a corresponding external connection wiring pad provided in the flexible cable by a corresponding wiring. Here, the reference voltage may be a voltage at a ground level.

The power supply voltage Vdd is applied to the light emitting pixel array 102 via the power supply wiring pad 123 and the power supply wiring 124. The cathode voltage Vcath is applied to the light emitting pixel array 102 via the cathode wiring pad 175 and a connection wiring 138 to the cathode electrode. The first power supply voltage Vddp for the peripheral circuit is applied to the vertical scanning circuit 104 and the signal output circuit 105 of the peripheral circuit via the power supply wiring pad 180 and a peripheral circuit power supply wiring 121. The first power supply voltage Vddp for the peripheral circuit is typically 5 V. The second power supply voltage Vdds for the peripheral circuit is applied to the signal output circuit 105 via the pad 177 and a wiring 122. A reference voltage Vss is applied to the vertical scanning circuit 104 and the signal output circuit 105 via the pad 178 and a reference voltage wiring 120. Signals for controlling the display and the light emitting device are supplied to the signal output circuit 105 via the pad 179. The wirings shown in FIG. 5 are merely examples, and can be changed, as appropriate, in accordance with the circuit configuration.

In this embodiment, the wirings for the power supply voltage Vdd and the cathode voltage Vcath can be arranged on the four sides around the arrangement region of the light emitting pixel array 102. The power supply voltage Vdd and the cathode voltage Vcath can be supplied from the wirings arranged on the four sides. A bypass capacitor 126 is arranged adjacent to the light emitting pixel array 102 and between the light emitting pixel array 102 and the vertical scanning circuit 104 as the peripheral circuit. A bypass capacitor 127 is arranged adjacent to the light emitting pixel array 102 and between the light emitting pixel array 102 and the signal output circuit 105 as the peripheral circuit. Each of bypass capacitors 130 and 133 is arranged adjacent to the light emitting pixel array 102. Each of the bypass capacitors 126, 127, 130, and 133 is provided between the arrangement region of the light emitting pixel array 102 and the edge portion of the substrate 171. It is sufficient that an electrode in a facing relationship with each of the bypass capacitors 126, 127, 130, and 133 is arranged to overlap one region between the edge portion of the substrate 171 and the arrangement region of the light emitting pixel array 102 in a planar view.

The bypass capacitors 126, 127, 130, and 133 can be provided between the power supply wiring 124 for the light emitting pixel array 102 and the connection wiring 138 electrically connected to the cathode electrodes, and arranged on the four sides to surround the light emitting pixel array 102. The total electric capacitance as the sum of the electric capacitances of the bypass capacitors 126, 127, 130, and 133 is preferably set to be larger than either the electric capacitance between the power supply voltage Vdd and the reference voltage Vss or the electric capacitance between the cathode voltage Vcath and the reference voltage Vss. Furthermore, the total electric capacitance may be set to be larger than either the electric capacitance between the first power supply voltage Vddp and the reference voltage Vss or the electric capacitance between the second power supply voltage Vdds and the reference voltage Vss. If the total electric capacitance of the bypass capacitors is set to be larger than the electric capacitance of the parasitic capacitance, the capacitive coupling between the power supply wiring 124 and the connection wiring 138 connected to the cathode electrode is strengthened. This is advantageous in suppressing the influence of the fluctuation of the power supply voltage on the display of the light emitting device. In FIG. 5, four bypass capacitors are provided, but the effect can be obtained with only one of them.

FIG. 6 is a sectional view showing the light emitting pixel array 102 and an adjacent portion thereof according to this embodiment. The pixel 103 includes an anode electrode 136, an organic layer 135 on the anode electrode, and the cathode electrode 125 on the organic layer 135. The organic layer 135 between the cathode electrode 125 and the anode electrode 136 includes a light emitting layer. Each of the cathode electrode 125 and the anode electrode 136 can be an electrode layer formed by a photolithography process in each layer. A color filter may be provided on the light emitting side of the pixel 103. Here, an example is shown in which a green color filter (G color filter) 131 is provided on one pixel, and a red color filter (R color filter) 132 is provided on another pixel. The anode electrodes of adjacent pixels are insulated from each other by a bank 134. The cathode electrode 125 is connected to a connection wiring 139 for supplying the cathode voltage in the end portion of the light emitting pixel array 102. In the end portion of the light emitting pixel array 102, the organic layer decreases in thickness and terminates. An electrode 140 is an electrode layer formed below (on the side opposite to the side where the cathode electrode 125 exists) the connection wiring 139 to the cathode electrode 125.

The first capacitive element 116 and the second capacitive element 117 are formed between the bottom surface of the anode electrode 136 and a region below the bottom surface, where transistors are formed. Each of the capacitive elements 116 and 117 is a capacitive element having an MIM structure in this embodiment, and includes an MIM electrode 141 and an MIM counter electrode 145 sandwiching an MIM insulating film 143. FIG. 6 shows one of the capacitive elements 116 and 117. The end portion of the light emitting pixel array 102 includes an organic layer decreasing portion 151 where the organic layer 135 decreases in thickness and terminates, and a cathode contact portion 153 where the connection wiring 139 for supplying the cathode voltage to the cathode electrode 125 is arranged.

In a region including the organic layer decreasing portion 151 and the cathode contact portion 153, an MIM insulating film 144 and an MIM electrode 142 and an MIM counter electrode 146 sandwiching the MIM insulating film 144 are provided below the bottom surface of the connection wiring 139, thereby forming a capacitance portion having an electric capacitance. In this embodiment, the capacitance portion has an MIM structure. In addition, a peripheral circuit portion 155 where the peripheral circuit is arranged is formed in the substrate.

In a planar view, the organic layer decreasing portion 151 and the cathode contact portion 153 are located between the light emitting pixel array 102 and the peripheral circuit portion 155. The organic layer decreasing portion 151 is a portion where a part of the organic layer 135 extends from the light emitting pixel array 102 and tapers off in thickness towards the end. The cathode contact portion 153 is a portion where the cathode electrode 125 comes into physical contact with the connection wiring 139, thereby electrically connected thereto.

The MIM electrode 142, the MIM insulating film 144, and the MIM counter electrode 146 form a capacitance portion having an electric capacitance. This capacitance portion corresponds to the bypass capacitor 126. That is, the bypass capacitor 126 is the MIM capacitance formed from the MIM electrode 142, the MIM insulating film 144, and the MIM counter electrode 146. The MIM electrode 142 of the MIM capacitance is electrically connected to the cathode electrode 125 and applied with the cathode voltage Vcath. The MIM counter electrode 146 is electrically connected to the power supply wiring 124 and applied with the power supply voltage Vdd.

Note that, it is also conceivable that the bypass capacitor is provided outside the light emitting device 101 to generate capacitive coupling between the power supply wiring 124 and the cathode electrode 125. However, since wiring inductance components generated in the power supply wiring 124 and the cathode electrode 125 in the light emitting pixel array 102 can increase, it may not be possible to ensure synchronicity of the Vcath with respect to the fluctuation of the Vdd. Therefore, as in this embodiment, the bypass capacitor 126 is arranged at a position overlapping the region adjacent to the light emitting pixel array 102, where the organic layer decreasing portion 151 and the cathode contact portion 153 are arranged. As a result, the bypass capacitor can be arranged near the light emitting pixel array 102, and the influence of the inductance can be reduced.

Each of the bypass capacitors 127, 130, and 133 is a capacitance portion having a structure similar to that of the bypass capacitor 126. In this embodiment, the bypass capacitor 126 is provided across the region including both the organic layer decreasing portion 151 and the cathode contact portion 153. When the bypass capacitor is arranged in this manner, the electric capacitance can be increased, and the coupling effect can also be increased. However, this effect can also be obtained even if the bypass capacitor 126 is arranged in the region of one of the organic layer decreasing portion 151 and the cathode contact portion 153.

The power supply voltage Vdd may be applied to the electrode 140 below the bottom surface of the connection wiring 139 to the cathode electrode, thereby forming an additional capacitance between wirings between the power supply voltage Vdd and the cathode voltage Vcath. In this case, the electrode 140 may be formed by the photolithography process for forming the power supply wiring 124. Note that it has been described that the column DAC circuit 108 and the column driver circuit 109 include the DAC circuits and the driver circuits for n columns, respectively, corresponding to the number of columns of the light emitting pixel array 102, but the number of each of the DAC circuits and the driver circuits can be made smaller than n by performing a switching operation with a switch.

### Second Embodiment

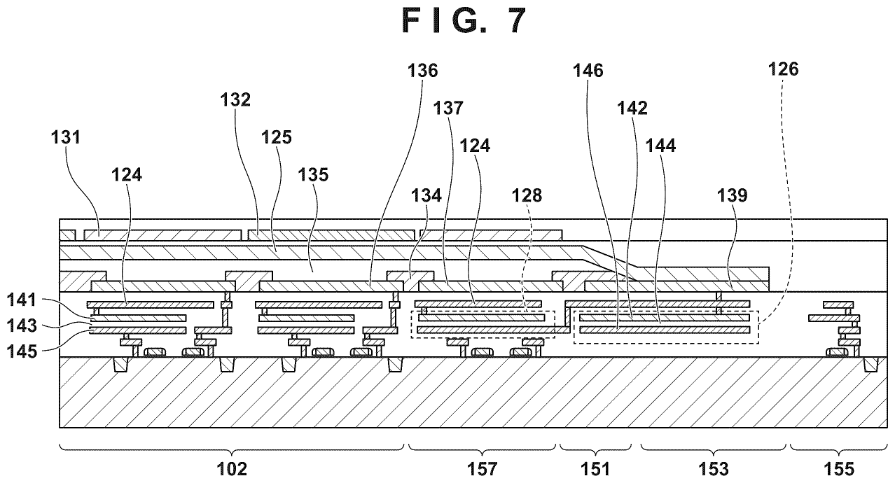

This embodiment is an example in which a bypass capacitor is formed in a region where a dummy pixel as a non-light emitting pixel is arranged around a light emitting pixel array 102. FIG. 7 is a sectional view of a light emitting device according to this embodiment. A color filter is arranged on each light emitting pixel that emits light. A dummy pixel array portion 157 where non-light emitting pixels are arranged is provided around the light emitting pixels. A bypass capacitor 128 is formed in the region of the dummy pixel array portion 157.

Each pixel in the light emitting pixel array 102 includes capacitive elements 116 and 117 in which the luminance signal of the pixel is written. The capacitive element is a capacitive portion corresponding to a portion indicated by an MIM electrode 141, an MIM insulating film 143, and an MIM counter electrode 145. Similar capacitive elements are provided in each light emitting pixel. On the other hand, the dummy pixel is normally formed around the light emitting pixel in the same process as the light emitting pixel. A capacitive portion having the MIM structure can also be formed in the dummy pixel, but the luminance signal need not be written in the capacitive portion having the MIM structure included in the dummy pixel. Accordingly, a power supply voltage Vdd and a cathode voltage Vcath can be wired to the capacitance portion of the dummy pixel via a wiring to a contact or the like, thereby using the capacitance portion as the bypass capacitor 128. Since the pixel in the dummy pixel array portion 157 need not emit light, the cathode voltage Vcath can be applied to an anode electrode 137 in the dummy pixel array portion 157. Other configurations such as the driving method are similar to those in the first embodiment. In this embodiment, the capacitive coupling between the power supply wiring and the wiring to the cathode can be strengthened by the capacitor 128.

In addition to the bypass capacitor 128, the sectional view of FIG. 7 shows a bypass capacitor 126 provided in an organic layer decreasing portion 151 and a cathode contact portion 153. This can increase the electric capacitance and strengthen the capacitive coupling. Even if the bypass capacitor 126 is not provided and only the bypass capacitor 128 in the dummy pixel array portion 157 is provided, the capacitive coupling can be strengthened, and the influence of the fluctuation of the power supply voltage on the display of the light emitting device can be suppressed.

### Third Embodiment

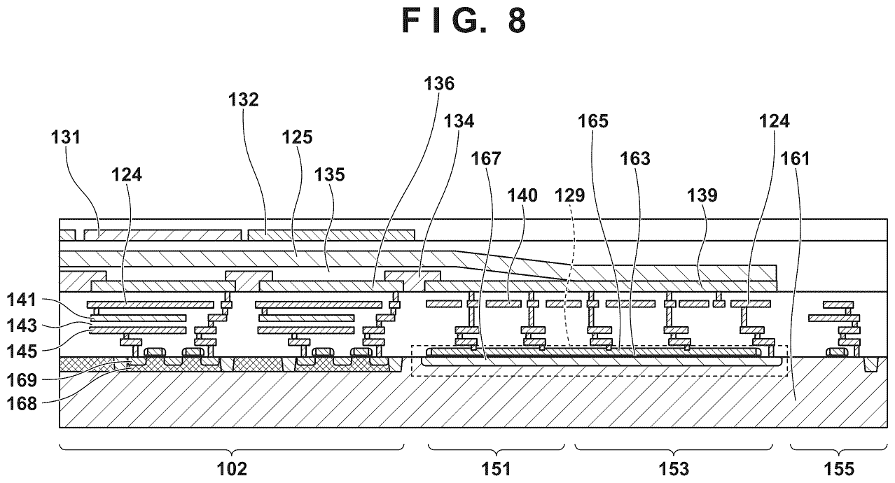

This embodiment is an example in which a bypass capacitor is formed as a capacitance portion having an MOS structure. FIG. 8 is a sectional view of a light emitting device according to this embodiment. In this embodiment, the substrate is a p-type semiconductor substrate 161. A gate insulating film 163 is arranged in the p-type semiconductor substrate 161, and a polysilicon electrode 165 is arranged on the gate insulating film 163. A diffusion layer 167 is provided below the gate insulating film 163. In addition, an n-type well 168 and a p-type diffusion layer 169 are shown. In this embodiment, a bypass capacitor 129 is arranged as a capacitance having an MOS structure below (on the p-type semiconductor substrate 161 side) the region where an organic layer decreasing portion 151 and a cathode contact portion 153 are arranged.

The bypass capacitor 129 includes the polysilicon electrode 165, the gate insulating film 163, and the diffusion layer 167. The polysilicon electrode 165 of the bypass capacitor 129 is electrically connected to a cathode electrode via a contact, thereby applied with a cathode voltage Vcath. A power supply voltage Vdd is applied to the diffusion layer 167. Also in this embodiment, the coupling between the power supply wiring and the wiring to the cathode can be strengthened by the bypass capacitor 129. Note that the bypass capacitor 129 is arranged across the organic layer decreasing portion 151 and the cathode contact portion 153 in FIG. 8, but the bypass capacitor 129 may be arranged in the region of one of the organic layer decreasing portion 151 and the cathode contact portion 153. The bypass capacitor according to this embodiment can be used alone or in combination with another embodiment.

### Fourth Embodiment

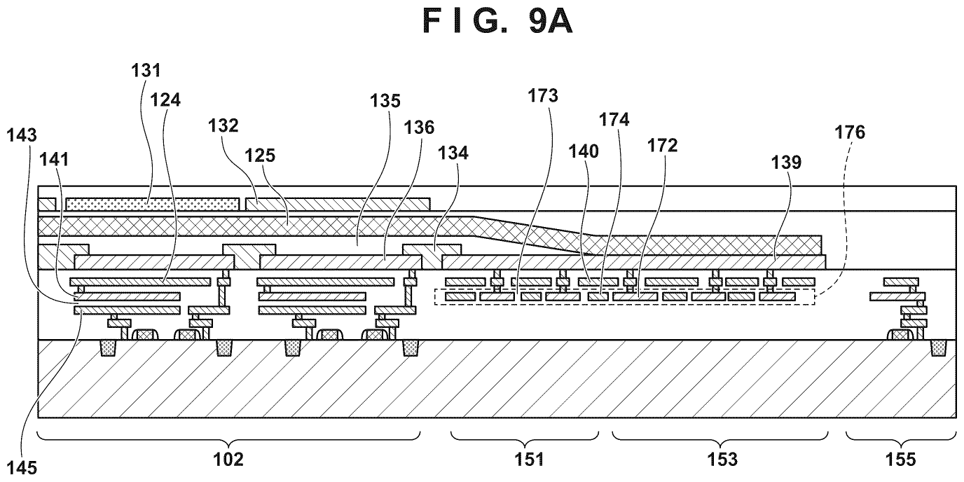

This embodiment is an example in which a bypass capacitor is formed as a capacitance portion having a Metal-Oxide-Metal (MOM) structure. FIG. 9A is a sectional view of a light emitting device according to this embodiment. In this embodiment, a bypass capacitor 176 is formed as a capacitance having an MOM structure below a region where an organic layer decreasing portion 151 and a cathode contact portion 153 are arranged. The capacitance of the MOM structure is formed from two metal electrodes in the same layer sandwiching an interlayer insulating region. The bypass capacitor 176 according to this embodiment is formed from an MOM electrode 172, an interlayer insulating region 173, and an MOM counter electrode 174. The bypass capacitor 176 can strengthen the capacitive coupling between the power supply wiring 124 and the cathode electrode 125.

FIG. 9B is a plan view of the bypass capacitor 176. In the bypass capacitor 176, the MOM electrode 172 and the MOM counter electrode 174 can be arranged close to each other in a comb-like manner. The interlayer insulating region 173 insulates them from each other.

Also in this embodiment, the coupling between the power supply wiring and the wiring to the cathode can be strengthened by the bypass capacitor 176. Note that the bypass capacitor 176 is arranged across the organic layer decreasing portion 151 and the cathode contact portion 153 in FIG. 9A, but the bypass capacitor 176 may be arranged in the region of one of the organic layer decreasing portion 151 and the cathode contact portion 153. The bypass capacitor according to this embodiment can be used alone or in combination with another embodiment.

### Fifth Embodiment

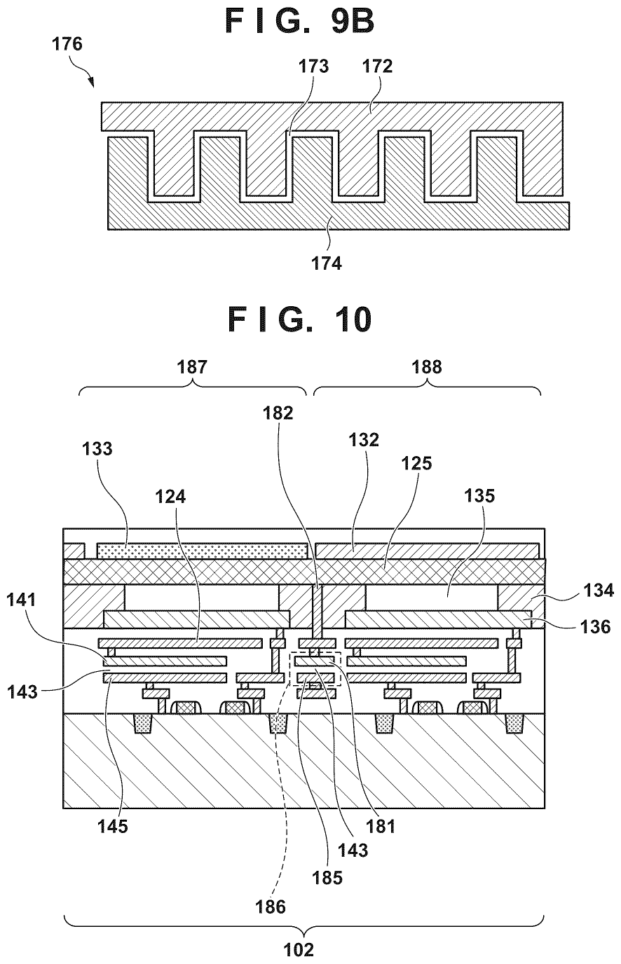

In this embodiment, the capacitive coupling between the power supply wiring and the cathode is increased by a bypass capacitor provided in the region of a light emitting pixel array 102. FIG. 10 is a sectional view of a light emitting device according to this embodiment. A bypass capacitor 186 as an MIM capacitance is formed between a G pixel 187 and an R pixel 188. The bypass capacitor 186 is formed from a second MIM electrode 181, an MIM insulating film 143, and a second MIM counter electrode 185. The bypass capacitor 186 can strengthen the capacitive coupling between the power supply wiring 124 and the cathode electrode 125.

In this embodiment, the second MIM electrode 181 is electrically connected to a cathode electrode 125 by a connection wiring 182. The connection wiring 182 is electrically insulated from an organic layer 135 by a bank 134. The second MIM counter electrode 185 is electrically connected to the power supply wiring.

The bypass capacitor according to this embodiment can be used alone or in combination with another embodiment.

### Application Examples of Light Emitting Device

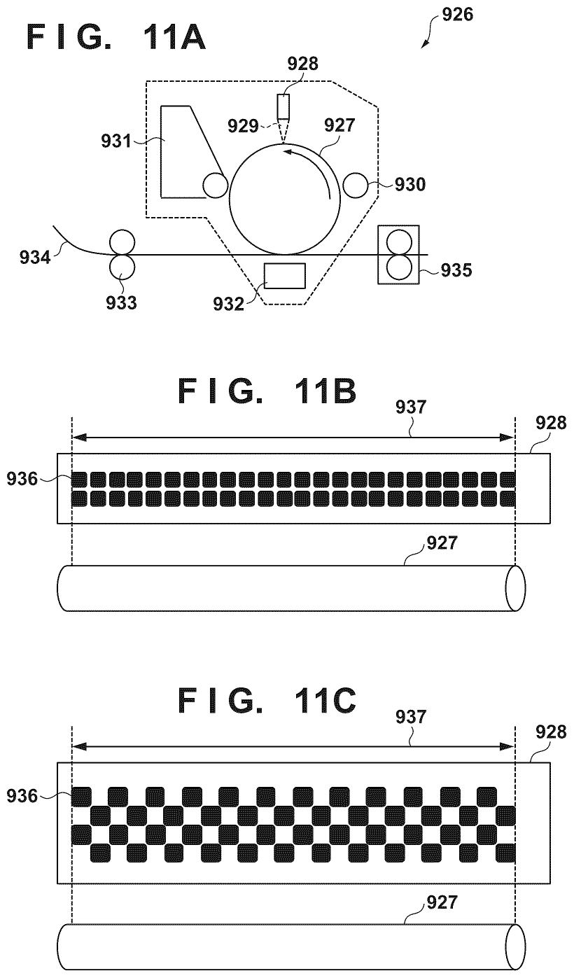

Examples in which the light emitting device according to each of the above-described first to fifth embodiments is applied to an apparatus will be described below. FIGS. 11A to 11C show an example in which the light emitting device according to each of the first to fifth embodiments is applied to an image forming device. FIG. 11A is a schematic view of an image forming device 926 according to this embodiment. The image forming device includes a photosensitive member 927, an exposure light source 928, a developing unit 931, a charging unit 930, a transfer device 932, a conveyance unit 933, and a fixing device 935.

Light 929 is emitted from an exposure light source 928, and an electrostatic latent image is formed on the surface of a photosensitive member 927. The light emitting device according to each of the first to fifth embodiments can be applied to the exposure light source 928. A developing unit 931 includes a developing agent such as a toner, and applies the developing agent to the exposed photosensitive member 927. A charging unit 930 charges the photosensitive member 927. A transfer device 932 transfers the developed image to a print medium 934. A conveyance unit 933 conveys the print medium 934. The print medium 934 can be, for example, paper. A fixing device 935 fixes the image formed on the print medium.

Each of FIGS. 11B and 11C is a schematic view showing a form in which a plurality of light emitting portions 936 are arranged in the exposure light source 928 on a long substrate. Arrow 937 indicates a direction parallel to the axis of the photosensitive member, which represents a column direction in which organic light emitting elements are arrayed. This column direction matches the direction of the axis upon rotating the photosensitive member 927. This direction can also be referred to as the long-axis direction of the photosensitive member.

FIG. 11B shows a form in which the light emitting portions are arranged along the long-axis direction of the photosensitive member. FIG. 11C shows a form which is different from that shown in FIG. 11B and in which the light emitting portions are arranged in the column direction alternately between the first column and the second column. The light emitting portions are arranged at different positions in the row direction between the first column and the second column.

As for the light emitting portions shown in FIG. 11C, the plurality of light emitting portions are arranged apart from each other in the first column. In the second column, the light emitting portion is arranged at the position corresponding to the space between the light emitting portions in the first column. That is, in the row direction as well, the plurality of light emitting portions are arranged apart from each other.

The arrangement shown in FIG. 11C can be referred to as, for example, an arrangement in a grid pattern, an arrangement in a staggered pattern, or an arrangement in a checkered pattern.

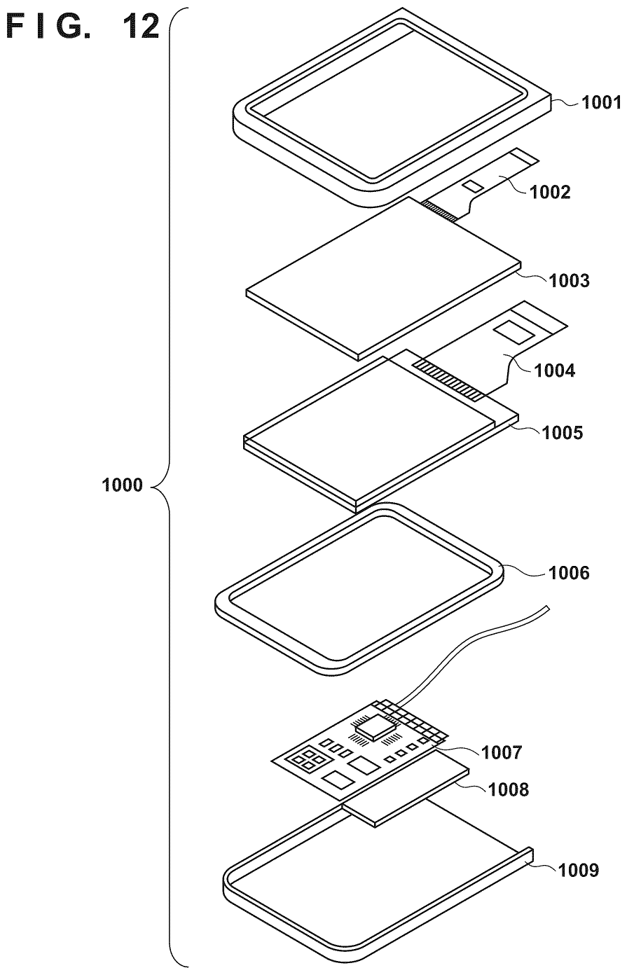

FIG. 12 is a schematic view showing an example of a display device that can use the light emitting device according to each of the above-described first to fifth embodiments. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 can be respectively connected to the touch panel 1003 and the display panel 1005. Transistors are arranged on the circuit board 1007. The battery 1008 is unnecessary if the display device is not a portable apparatus. Even when the display device is a portable apparatus, the battery 1008 may be provided at another position.

The display device according to this embodiment can include color filters of red, green, and blue. The color filters of red, green, and blue can be arranged in a delta array.

The display device according to this embodiment can also be used for a display unit of a portable terminal. At this time, the display unit can have both a display function and an operation function. Examples of the portable terminal are a portable phone such as a smartphone, a tablet, and a head mounted display.

The display device according to this embodiment can be used for a display unit of an image capturing device including an optical unit having a plurality of lenses, and an image capturing element for receiving light having passed through the optical unit. The image capturing device can include a display unit for displaying information acquired by the image capturing element. In addition, the display unit can be either a display unit exposed outside the image capturing device, or a display unit arranged in the finder. The image capturing device can be a digital camera or a digital video camera.

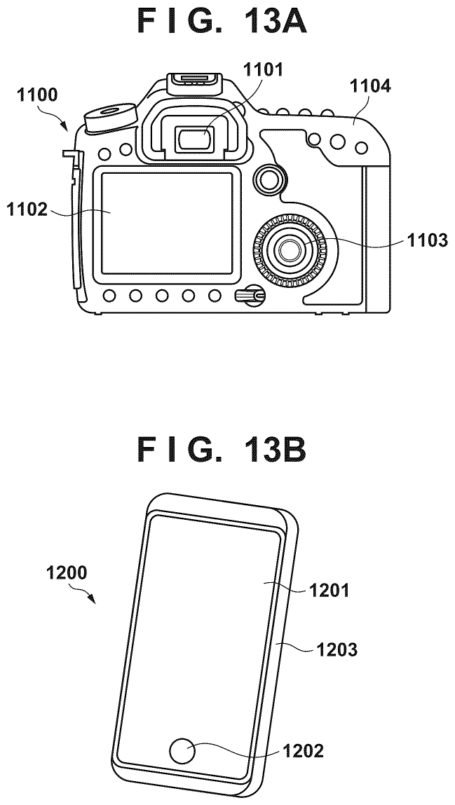

FIG. 13A is a schematic view showing an example of an image capturing device using, as a display device, the light emitting device according to this embodiment. An image capturing device 1100 can include a viewfinder 1101, a rear display 1102, an operation unit 1103, and a housing 1104. The viewfinder 1101 may include the display device using the light emitting device according to each of the first to fifth embodiments. In this case, the display device can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. Therefore, the display device using the light emitting device according to each of the first to fifth embodiments is preferably used. The organic light emitting element has a high response speed as a light emitting element. Therefore, the display device using the organic light emitting element is preferably used for the devices that require a high display speed.

The image capturing device 1100 includes an optical unit (not shown). This optical unit has a plurality of lenses, and forms an image on an image capturing element that is accommodated in the housing 1104. The focal points of the plurality of lenses can be adjusted by adjusting the relative positions. This operation can also automatically be performed. The image capturing device may be called a photoelectric conversion device. Instead of sequentially capturing an image, the photoelectric conversion device can include, as an image capturing method, a method of detecting the difference from a previous image, a method of extracting an image from an always recorded image, or the like.

FIG. 13B is a schematic view showing an example of an electronic apparatus including the light emitting device according to each of the first to fifth embodiments. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit can also be a biometric authentication unit that performs unlocking or the like by authenticating the fingerprint. The electronic apparatus including the communication unit can also be regarded as a communication apparatus. The electronic apparatus can further have a camera function by including a lens and an image capturing element. An image captured by the camera function is displayed on the display unit. Examples of the electronic apparatus are a smartphone and a notebook computer.

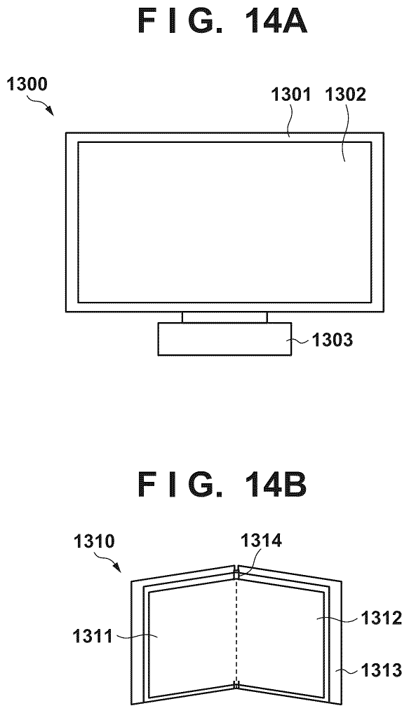

FIGS. 14A and 14B are schematic views showing examples of a display device using the light emitting device according to each of the first to fifth embodiments. FIG. 14A shows a display device such as a television monitor or a PC monitor. A display device 1300 includes a frame 1301 and a display unit 1302. When the light emitting device according to the above-described embodiment is used for the display unit 1302, deterioration of a displayed image can be suppressed.

The display device 1300 includes a base 1303 that supports the frame 1301 and the display unit 1302. The base 1303 is not limited to the form shown in FIG. 14A. The lower side of the frame 1301 may also function as the base.

In addition, the frame 1301 and the display unit 1302 can be bent. The radius of curvature in this case can be 5,000 (inclusive) mm to 6,000 (inclusive) mm.

FIG. 14B is a schematic view showing another example of the display device. A display device 1310 shown in FIG. 14B can be folded, that is, the display device 1310 is a so-called foldable display device. The display device 1310 includes a first display unit 1311, a second display unit 1312, a housing 1313, and a bending point 1314. The first display unit 1311 and the second display unit 1312 may include the light emitting device according to each of the first to fifth embodiments. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

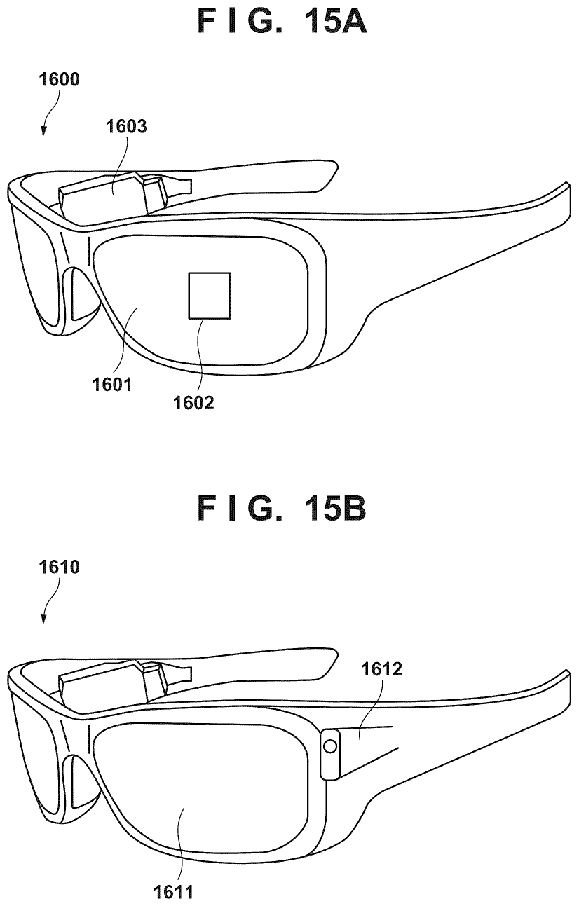

An example of a display device using the light emitting device according to each of the first to fifth embodiments will be described with reference to FIGS. 15A and 15B. The display device can be applied to a system that can be worn as a wearable device such as smartglasses, an HMD, or a smart contact lens. The display device used for such applications can include an image capturing device capable of photoelectrically converting visible light and a display device capable of emitting visible light.

Glasses 1600 (smartglasses) according to one application example will be described with reference to FIG. 15A. An image capturing device 1602 such as a CMOS sensor or an SPAD is provided on the surface side of a lens 1601 of the glasses 1600. In addition, the display device of each of the above-described embodiments is provided on the back surface side of the lens 1601.

The glasses 1600 can further include a control device 1603. The control device 1603 functions as a power supply that supplies power to the image capturing device 1602 and the display device according to each embodiment. In addition, the control device 1603 controls the operations of the image capturing device 1602 and the display device. An optical system configured to condense light to the image capturing device 1602 is formed on the lens 1601.

Glasses 1610 (smartglasses) according to one application example will be described with reference to FIG. 15B. The glasses 1610 includes a control device 1612. An image capturing device corresponding to the image capturing device 1602 and a display device are mounted on the control device 1612. An optical system configured to project light emitted from the display device in the control device 1612 is formed in a lens 1611, and an image is projected to the lens 1611. The control device 1612 functions as a power supply that supplies power to the image capturing device and the display device, and controls the operations of the image capturing device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to this embodiment can include an image capturing device including a light receiving element, and a displayed image on the display device can be controlled based on the line-of-sight information of the user from the image capturing device.

More specifically, the display device can decide a first display region at which the user is gazing and a second display region other than the first display region based on the line-of-sight information. The first display region and the second display region may be decided by the control device of the display device, or those decided by an external control device may be received. In the display region of the display device, the display resolution of the first display region may be controlled to be higher than the display resolution of the second display region. That is, the resolution of the second display region may be lower than that of the first display region.

In addition, the display region includes a first display region and a second display region different from the first display region, and a region of higher priority is decided from the first display region and the second display region based on line-of-sight information. The first display region and the second display region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that Artificial Intelligence (AI) may be used to decide the first display region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on line-of-sight detection, this can preferably be applied to smartglasses further including an image capturing device configured to capture the outside. The smartglasses can display captured outside information in real time.

As has been described above, by using the device using the organic light emitting element according to the embodiment, display with fine image quality and stable even for a long period of time is possible.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-017431, filed Feb. 7, 2024 and Japanese Patent Application No. 2024-219010, filed Dec. 13, 2024, which are hereby incorporated by reference herein in their entirety.

What is claimed is:

1. A light emitting device comprising a substrate that includes a light emitting pixel array including a plurality of light emitting pixels each including a light emitting element and a driving transistor configured to drive the light emitting element, a power supply wiring configured to supply a power supply voltage to the driving transistor, and a capacitance portion including a first electrode and a second electrode,
wherein
the light emitting element includes a first electrode layer, a light emitting layer arranged on the first electrode layer, and a second electrode layer arranged on the light emitting layer, and
the first electrode and the second electrode are located at positions lower than a bottom surface of the first electrode layer, the first electrode is electrically connected to the power supply wiring, and the second electrode is electrically connected to the second electrode layer.

2. The device according to claim 1, wherein the capacitance portion is arranged to overlap a first region between an edge portion of the substrate and the light emitting pixel array in a planar view.

3. The device according to claim 1, wherein a wiring electrically connecting the second electrode and the second electrode layer is provided between pixels in the light emitting pixel array.

4. The device according to claim 1, wherein the capacitance portion has an MOM structure.

5. The device according to claim 2, wherein the first region includes an end portion of an organic layer including the light emitting layer.

6. The device according to claim 2, wherein the first region includes a region where a plurality of non-light emitting pixels are arranged in a planar view, and each of the plurality of non-light emitting pixels includes the capacitance portion.

7. The device according to claim 1, wherein a peripheral circuit configured to control the light emitting pixel array is provided in the substrate, and the first electrode and the second electrode are arranged between a region where the peripheral circuit is arranged and the light emitting pixel array in a planar view.

8. The device according to claim 1, wherein the capacitance portion has an MIM structure.

9. The device according to claim 1, wherein the capacitance portion has an MOS structure.

10. The device according to claim 1, wherein the substrate further includes a first wiring configured to supply a voltage to the second electrode layer, and a second wiring configured to supply a reference voltage between the power supply voltage and a voltage applied to the second electrode layer.

11. The device according to claim 10, wherein an electric capacitance between the power supply wiring and the first wiring is larger than either one of an electric capacitance between the power supply wiring and the second wiring and an electric capacitance between the first wiring and the second wiring.

12. The device according to claim 1, wherein the capacitance portion is arranged in a region outside four sides of the light emitting pixel array.

13. The device according to claim 1, wherein the first electrode is an anode electrode of the light emitting element, and the second electrode is a cathode electrode of the light emitting element.

14. An image forming device comprising a photosensitive member, an exposure light source configured to expose the photosensitive member, a developing device configured to apply a developing agent to the exposed photosensitive member, and a transfer device configured to transfer an image developed by the developing device to a print medium,
wherein the exposure light source includes a light emitting device defined in claim 1.

15. An image capturing device comprising an optical unit including a plurality of lenses, an image capturing element configured to receive light having passed through the optical unit, and a display unit configured to display an image captured by the image capturing element,
wherein the display unit includes a light emitting device defined in claim 1.

16. A display device comprising a display unit including a light emitting device defined in claim 1, and a housing provided with the display unit.

17. An electronic apparatus comprising a display unit including a light emitting device defined in claim 1, a housing provided with the display unit, and a communication unit provided in the housing and configured to communicate with an outside.

18. A wearable device including a display device configured to display an image,
wherein the display device includes a light emitting device defined in claim 1.
